(19) United States
(12) Patent Application Publication
(10) Pub. No.: US 2011/0111552 A1
(43) Pub. Date: May 12, 2011

(54) Method for forming organic layers of electronic devices by contact printing

(75) Inventors: Jwo-Huei Jou, Hsinchu (TW); Sun-Zen Chen, Hsinchu (TW); Shiang-Hau Peng, Hsinchu (TW); Bo-Shian Wu, Hsinchu (TW); Chin-Yeh Chang, Hsinchu (TW); Po-Hsuan Chiang, Hsinchu (TW)

(73) Assignee: National Tsing Hua University, Hsinchu (TW)

(21) Appl. No.: 12/801,761

(22) Filed: Jun. 24, 2010

(30) Foreign Application Priority Data
Nov. 12, 2009 (TW) 098138359

(51) Int. Cl. H01L 51/40; B05D 5/12

(52) U.S. Cl. 438/99; 264/104; 257/E51.005

(57) ABSTRACT

A method for forming organic layers of electronic devices by contact printing is disclosed, which comprises: (A) providing a substrate, which has an electrode formed thereon; (B) coating an organic material ink onto a mold; (C) applying the ink-coated mold onto the substrate, to transfer the organic material ink onto the electrode of the substrate and then to form an organic layer; and (D) forming another electrode on the organic layer. In addition, after the step (C) is completed, the steps (B) to (C) can be repeated once or several times to form series of organic layers, if needed.

### BACKGROUND OF THE INVENTION

1. Field of the Invention

The present invention relates to a method for forming organic layers of electronic devices and, more particularly, to a method for forming organic layers of electronic devices by a contact printing process, which can be used to prepare the large-area organic layers of the electronic devices quickly.

2. Description of Related Art

Currently, electronic devices are used widely in daily lives. Organic materials are inexpensive and easily available. So, various researches and studies are trying to fabricate the electronic devices by using organic materials, for the sake of reducing the production cost. Nowadays, the organic electronic devices, such as organic thin film transistors (OTFTs), organic memories, and organic radical batteries, are being developed.

Conventional methods used for forming organic layers of the electronic devices are vacuum evaporation, spin coating, or inkjet printing. However, there are still some disadvantages about these methods.

When the vacuum evaporation is performed, vacuum equipment has to be used to generate a vacuum condition. However, the vacuum equipment is very expensive, which results in the increase of the production cost. Also, it is difficult to prepare large-area organic layers by using the vacuum evaporation. Although the large-area organic layers can be formed in a low-cost way through the spin coating, only the substrate with a plane surface can be coated. Hence, the spin coating cannot be used on the substrate with curved surfaces, or the substrate with patterns.

Therefore, it is desirable to provide a method, which can prepare the organic layers of the electronic devices in a rapid and inexpensive way, in order to reduce the production cost of the electronic devices. Also, it is desirable to provide a method to accomplish the purpose of forming large-area and patterned organic layers.

### SUMMARY OF THE INVENTION

The object of the present invention is to provide a method for forming organic layers of electronic devices, to prepare the large-area organic layers of the electronic devices in a simple and rapid way.

To achieve the object, the method for forming organic layers of an electronic device of the present invention comprises the following steps: (A) providing a substrate with a first electrode formed thereon; (B) coating a first mold with a first organic material ink; (C) applying the first mold coated with the first organic material ink onto the substrate, to transfer the first organic material ink onto the first electrode of the substrate to form an organic layer; and (D) forming a second electrode on the organic layer.

The method of the present invention can prepare the organic layer of the electronic device in a rapid, simple and low-cost way, through a contact printing process. Also, the mold used in the method of the present invention can be reused and easily mass-produced, so the production cost can be reduced. Furthermore, large-area electronic devices can be fabricated through the method of the present invention because the contact printing process is capable of production in large area. In addition, not only the substrate with a plane surface but also the substrate with a curved surface or a flexible substrate can be used in the method of the present invention. Hence, it is possible to form organic layers on the patterned substrate.

The method of the present invention may further comprise a step (C1) and a step (C2) after the step (C). (C1) coating a second mold with a second organic material ink; and (C2) applying the second mold coated with the second organic material ink onto the substrate, to form another organic layer. In addition, the method of the present invention may also comprise a step (C′) after the step (C2): repeating the step (C1) and the step (C2) sequentially, to form plural organic layers.

According to the method of the present invention, the first mold can be coated with the first organic material ink by spin coating, dip coating, roll coating, or printing in the step (B). In addition, the second mold may be coated with the second organic material ink by spin coating, dip coating, roll coating, or printing in the step (C1).

Furthermore, according to the method of the present invention, the first mold and the following molds can be the same mold or different molds. The first mold and the following molds may have its own patterns formed thereon, respectively. In addition, the material of the first mold or the following molds can be any mold material generally used in a contact printing process. Preferably, the material of the first mold or the following molds is poly(dimethyl siloxane) (PDMS). The free energy of the surface of the mold made from PDMS is extremely low, so the organic material ink can chemically/physically adhere to the substrate, when the organic material ink comes into contact with the substrate.

According to the method of the present invention, the substrate may be a Si substrate, a glass substrate, a quartz substrate, or a plastic substrate.

When the method of the present invention is applied to form the organic layer of an organic thin film transistor, the first organic material ink and the following organic material inks can be the same organic material or different organic materials. In addition, each of the first organic material ink and the following organic material inks are respectively selected from the group consisting of P3HT, pentacene, a combination thereof, and other electric conducting materials.

When the method of the present invention is applied to form the organic layer of an organic memory, the first organic material ink and the following organic material inks can be the same organic material or different organic materials. In addition, each of the first organic material ink and the following organic material inks can be respectively selected from the group consisting of polyvinylidene, polyvinylidene fluoride (PVDF), a copolymer of polyvinylidene and polyvinylidene fluoride, trifluorothylene (TrFE), porphyrin, 2-amino-1H-imidazole-4,5-dicarbonitrile (AIDCN), AIDCN derivatives, a combination thereof, and other electric conducting materials.

When the method of the present invention is applied to form the organic layer of an organic battery, the first organic material ink and the following organic material inks can be the same organic material or different organic materials. In addition, each of the first organic material ink and the following organic material inks can be respectively selected from the group consisting of nitrogen oxide, nitrogen oxide derivatives, graphite, a combination thereof, and other electric conducting materials.

The method of the present invention can apply to form organic layers of electronic devices, such as organic thin film transistors, organic memories, and organic batteries. The method of the present invention can form the large-area organic layers of the electronic devices rapidly and inexpensively, compared to the conventional method such as a vacuum evaporation process. Also, the present invention can form patterned organic layers or form organic layers on curved substrates, which cannot be accomplished by use of the spin coating process.

### BRIEF DESCRIPTION OF THE DRAWINGS

FIGS. 1A to 1E are the sectional views illustrating the process for forming an organic thin film transistor in Embodiment 1 of the present invention;

FIGS. 2A to 2E are the sectional views illustrating the process for forming an organic thin film transistor in Embodiment 2 of the present invention; and

FIGS. 3A to 3E are the sectional views illustrating the process for forming an organic memory in Embodiment 3 of the present invention;

### DETAILED DESCRIPTION OF THE PREFERRED EMBODIMENT

Hereinbelow, the present invention will be described in detail with reference to the Embodiments. The present invention may, however, be embodied in many different forms and should not be construed as being limited to the Embodiments set forth herein. Rather, these Embodiments are provided to fully convey the concept of the invention to those skilled in the art.

### Embodiment 1

### Preparation of an Organic Thin Film Transistor

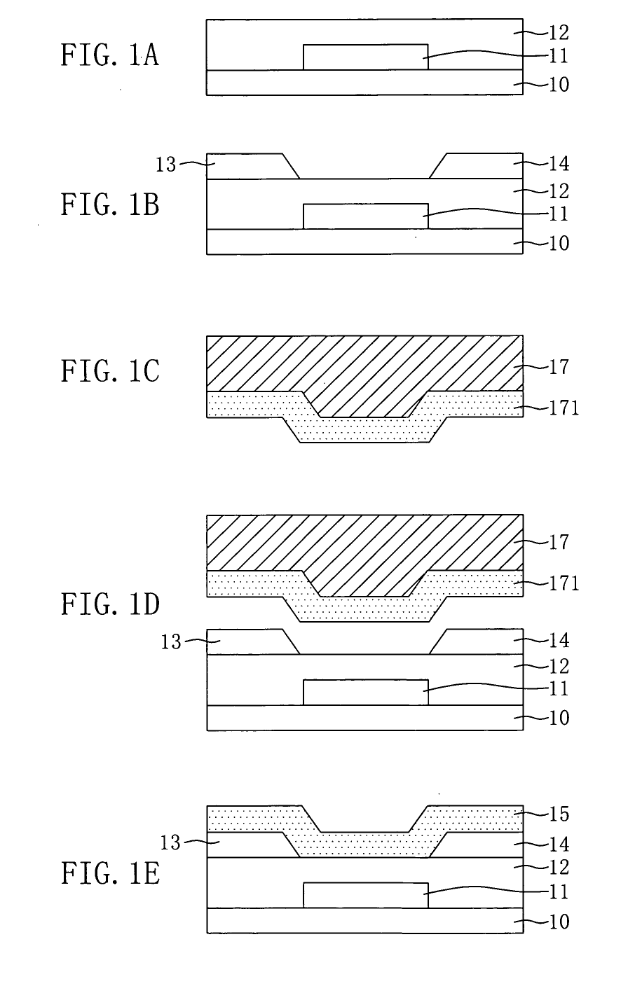

FIGS. 1A to 1E are the sectional views illustrating the process for forming an organic thin film transistor in the present embodiment.

First, as shown in FIG. 1A, a substrate 10 was provided, and a gate 11 was formed thereon. A gate insulating layer 12 made from silicon nitride was formed on the substrate 10 and the gate 11 through a spray coating process, and then a source 13 and a drain 14 were formed on the gate insulating layer 12, as shown in FIG. 1B.

As shown in FIG. 1C, a first mold 17 made from PDMS was provided, wherein the first mold 17 has a pattern formed thereon, and the pattern corresponds to the source 13 and the drain 14 on the gate insulating layer 12. Then, the first mold 17 was coated with a first organic material ink 171 by a dip coating process. In the present embodiment, the material of the first organic material ink 171 is pentacene.

When a contact printing process was performed with the first mold 17 made from PDMS, the pattern on the first mold 17 can contact the printed surface closely because PDMS is a soft material.

As shown in FIG. 1D, the first mold 17 coated with the first organic material ink 171 was pressed onto the substrate 10, and the first organic material ink 171 was transferred to the gate insulating layer 12, the source 13, and the drain 14 of the substrate 10, to form an organic layer 15, as shown in FIG. 1E. In the present embodiment, the organic layer 15 was used as an active layer of an organic thin film transistor.

After completion of the aforementioned process, a bottom contact OTFT of the present invention was obtained. Compared to the method using a spray coating process or an evaporation process to form the organic layer, the organic layer of the present embodiment can be manufactured rapidly and inexpensively through a contact printing process. Also, it is possible to manufacture the organic layer with large area by use of the contact printing process.

### Embodiment 2

### Preparation of an Organic Thin Film Transistor

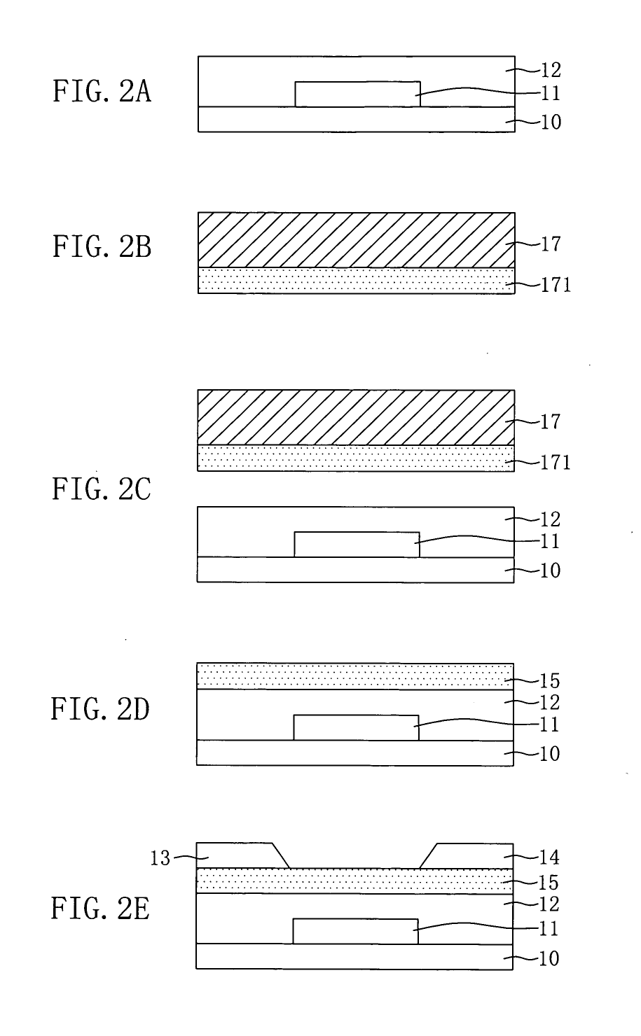

FIGS. 2A to 2E are sectional views illustrating the process for forming an organic thin film transistor in the present embodiment.

First, as shown in FIG. 2A, a substrate 10 was provided, and a gate 11 was formed thereon. Then, a gate insulating layer 12 made from silicon nitride was formed on the substrate 10 and the gate 11 through a spray coating process.

As shown in FIG. 2B, a first mold 17 made from PDMS was provided, and the first mold 17 was coated with a first organic material ink 171 through a spin coating process.

Then, as shown in FIG. 2C, the first mold 17 coated with the first organic material ink 171 was pressed onto the substrate 10, and the first organic material ink 171 was transferred to the gate insulating layer 12 of the substrate, to form an organic layer 15, as shown in FIG. 2D. In the present embodiment, the organic layer 15 was used as an active layer of an organic thin film transistor.

Finally, a source 13 and a drain 14 were formed on the organic layer, to obtain a top contact OTFT of the present embodiment.

### Embodiment 3

### Preparation of an Organic Memory

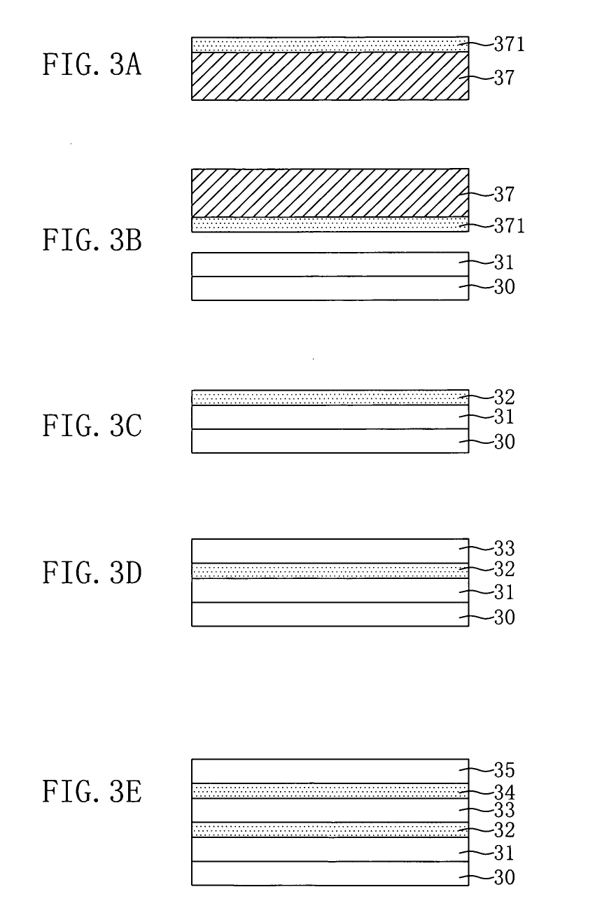

FIGS. 3A to 3E are sectional views illustrating the process for forming an organic memory in the present embodiment.

First, as shown in FIG. 3A, a first mold 37 was coated with a first organic material ink 371. In the present embodiment, the first organic material ink 371 is AIDCN.

As shown in FIG. 2B, a substrate 30 was provided, and a first electrode 31 was formed thereon. In the present embodiment, the substrate 30 was an Si substrate with an SiO₂ layer formed thereon, and the first electrode 31 was an Al electrode formed on the SiO₂ layer.

Then, the first mold 37 coated with the first organic material ink 371 was pressed onto the substrate 30, and the first organic material ink 371 was transferred onto the first electrode 31 of the substrate 30 to obtain an organic layer 32, as shown in FIG. 3C.

As shown in FIG. 3D, a metal layer 33 was formed on the organic layer 32 through an evaporation process. In the present embodiment, the material of the metal layer 33 was Al.

After the metal layer 33 was formed, the first mold 37 was coated with the first organic material ink 371 again. Then, a contact printing process was performed to form another organic layer 34, as shown in FIG. 3E. Finally, a second electrode 35 was formed on the organic layer 34 through an evaporation process.

After the aforementioned process was finished, the organic memory of the present embodiment was obtained. In the present embodiment, each of the organic layers was formed through the contact printing process, and the same first mold was used to form each organic layer. In addition, the method for forming the organic layer of the present embodiment can prepare the organic layers rapidly and inexpensively, compared to the method using an evaporation process to form the organic layers. Also, the problem that organic layers with large area cannot be prepared through the evaporation process, can be solved by using the method of the present embodiment. Hence, not only the same mold can be reused, but also the large-area organic layers of the organic memory can be obtained rapidly and inexpensively, according to the process of the present embodiment.

Although the present invention has been explained in relation to its preferred embodiment, it is to be understood that many other possible modifications and variations can be made without departing from the scope of the invention as hereinafter claimed.

What is claimed is:

1. A method for forming organic layers of an electronic device, comprising the following steps:
(A) providing a substrate with a first electrode formed thereon;
(B) coating a first mold with a first organic material ink;
(C) applying the first mold coated with the first organic material ink onto the substrate, to transfer the first organic material ink onto the first electrode of the substrate to form an organic layer; and
(D) forming a second electrode on the organic layer.

2. The method as claimed in claim 1, further comprising a step (C1) and a step (C2) after the step (C):
(C1) coating a second mold with a second organic material ink; and
(C2) applying the second mold coated with the second organic material ink onto the substrate, to form another organic layer.

3. The method as claimed in claim 2, further comprising a step (C′) after the step (C2):
(C′) repeating the step (C1) and the step (C2) sequentially, to form plural organic layers.

4. The method as claimed in claim 1, wherein the first mold is coated with the first organic material ink by spin coating, dip coating, roll coating, or printing in the step (B).

5. The method as claimed in claim 2, wherein the second mold is coated with the second organic material ink by spin coating, dip coating, roll coating, or printing in the step (C1).

6. The method as claimed in claim 1, wherein the first mold has a pattern formed thereon.

7. The method as claimed in claim 2, wherein the second mold has a pattern formed thereon.

8. The method as claimed in claim 1, wherein the material of the first mold is PDMS.

9. The method as claimed in claim 2, wherein the material of the second mold is PDMS.

10. The method as claimed in claim 1, wherein the substrate is an Si substrate, a glass substrate, a quartz substrate, or a plastic substrate.

11. The method as claimed in claim 1, wherein the electronic device is an organic thin film transistor.

12. The method as claimed in claim 11, wherein the first organic material ink is selected from the group consisting of P3HT, pentacene, and a combination thereof.

13. The method as claimed in claim 2, wherein the second organic material ink is selected from the group consisting of P3HT, pentacene, and a combination thereof.

14. The method as claimed in claim 1, wherein the electronic device is an organic memory.

15. The method as claimed in claim 14, wherein the first organic material ink can be selected from the group consisting of polyvinylidene, polyvinylidene fluoride (PVDF), a copolymer of polyvinylidene and polyvinylidene fluoride, trifluorothylene (TrFE), porphyrin, 2-amino-1H-imidazole-4,5-dicarbonitrile (AIDCN), AIDCN derivatives, and a combination thereof.

16. The method as claimed in claim 2, wherein the second organic material ink can be selected from the group consisting of polyvinylidene, polyvinylidene fluoride (PVDF), a copolymer of polyvinylidene and polyvinylidene fluoride, trifluorothylene (TrFE), porphyrin, 2-amino-1H-imidazole-4,5-dicarbonitrile (AIDCN), AIDCN derivatives, and a combination thereof.

17. The method as claimed in claim 1, wherein the electronic device is an organic battery.

18. The method as claimed in claim 17, wherein the first organic material ink can be selected from the group consisting of nitrogen oxide, graphite, and a combination thereof.

19. The method as claimed in claim 2, wherein the second organic material ink can be selected from the group consisting of nitrogen oxide, graphite, and a combination thereof.
